(19) United States
(12) Patent Application Publication
(10) Pub. No.: US 2024/0203727 A1
(43) Pub. Date: Jun. 20, 2024

(54) METHOD OF DEPOSITING SILICON-BASED MATERIAL AND PRECURSORS FOR THE SAME

(71) Applicant: ASM IP Holding B.V., Almere (NL)

(72) Inventors: Tao Xu, Helsinki (FI); Viljami Pore, Helsinki (FI)

(21) Appl. No.: 18/537,984

(22) Filed: Dec. 13, 2023

Related U.S. Application Data
(60) Provisional application No. 63/433,026, filed on Dec. 16, 2022.

(51) Int. Cl. H01L 21/02; C23C 16/36; C23C 16/455; H01J 37/32

(52) U.S. Cl. CPC H01L 21/02167; C23C 16/36; C23C 16/45531; C23C 16/45536; C23C 16/45553; H01J 37/32449; H01L 21/02274; H01J 2237/3321

(57) ABSTRACT

The disclosure relates to methods of depositing a material including silicon, carbon and nitrogen on a substrate. The methods include providing the substrate in a reaction chamber, providing a material precursor into the reaction chamber in a vapor phase and providing active species generated from plasma into the reaction chamber to form a material including silicon, carbon and nitrogen on the substrate. In the disclosure, the material precursor includes a silicon-containing azole. The disclosure further relates to processing assemblies for the manufacture of semiconductor devices.

This application claims priority to and the benefit of U.S. Provisional Application No. 63/433,026, filed Dec. 16, 2022, the entirety of which is incorporated by reference herein.

### FIELD OF INVENTION

The present disclosure relates to methods, precursors and apparatuses for the deposition of material comprising silicon. In aspects, the disclosure relates to methods and apparatuses for manufacturing semiconductor devices and conformal silicon-based material layers.

### BACKGROUND OF THE DISCLOSURE

Silicon-containing materials are a core material group in semiconductor devices. They are used to perform various functions, such as dielectric materials, insulators, etch stop layers and barrier layers in both memory and logic devices. Depending on the application, silicon-containing materials are deposited either conformally or to fill a gap in a three-dimensional feature of a device or between devices.

The properties of a silicon-containing material depend both on its composition and the way it is formed. In the field of vapor deposition, methods have been developed to deposit silicon nitride materials in various ways. However, in many applications, carbon-containing silicon nitride materials are sought after, as carbon incorporation may improve the etch resistance and lower the k value of the material. This may be necessary to further improve semiconductor device performance and allow the production of thinner layers to reduce device dimensions. Methods for depositing such materials are lacking, and thus there is need in the art for improved methods and precursors for depositing silicon-based materials, and material comprising silicon, carbon and nitrogen in particular.

Specifically, SiCN layers can be used in low-k spacer applications and especially as a precursor layers for forming SiOCN layers. Conformal, low wet etch rate SiCN films may be needed as cover spacers in future CFET devices. The drawbacks in current SiCN deposition methods are poor conformality and the difficulty in getting high and uniform carbon content along the vertical structures. Further, high deposition temperatures, such as above 600° C. are used, which are not compatible with the thermal budgets of many processes.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing material comprising silicon and layers comprising the same, as well as to precursors used in deposition processes for materials comprising silicon. Embodiments of the current disclosure further relate to methods of fabricating semiconductor devices, and to semiconductor processing assemblies.

In one aspect, a method of depositing a material comprising silicon, carbon and nitrogen on a substrate is disclosed. The method comprises providing the substrate in a reaction chamber, providing a material precursor into the reaction chamber in a vapor phase and providing active species generated from plasma into the reaction chamber to form a material comprising silicon, carbon and nitrogen on the substrate. In the disclosure, the material precursor comprises a silicon-containing azole.

In some embodiments, the active species are generated from a gas comprising a noble gas. In some embodiments, the noble gas is argon. In some embodiments, the active species are generated from a gas comprising argon and hydrogen.

In some embodiments, the material precursor comprises an alkylsilyl group bonded to the azole ring. In some embodiments, the alkylsilyl group has the formula —SiR₃, and each R is a H or a C1 to C4 alkyl, with the proviso that at least one R is an alkyl. In some embodiments, all three R are C1 to C4 alkyl groups. In some embodiments, all R are methyl or ethyl.

In some embodiments, the alkylsilyl group is bonded to the azole through a nitrogen atom.

In some embodiments, the azole of the material precursor consists of carbon, nitrogen and hydrogen. In some embodiments, the azole of the material precursor is selected from a group consisting of imidazole, pyrazole, triazole, tetrazole, pentazole.

In some embodiments, the azole of the material precursor consists of carbon, nitrogen, oxygen and hydrogen. In some embodiments, the azole of the material precursor is selected from a group consisting of oxazole, isoxazole and oxadiazole.

In some embodiments, the azole of the material precursor consists of carbon, nitrogen, sulfur and hydrogen. In some embodiments, the material precursor is selected from a group consisting of thiazole, isothiazole and thiadiazole.

In some embodiments, the material precursor is selected from a group consisting of 1-trimethylsilylimidazole and 1-trimethylsilyl-1,2,4-triazole.

In some embodiments, the material precursor and the active species are provided into the reaction chamber cyclically. In some embodiments, the material precursor and active species are provided into the reaction chamber alternately and sequentially. In some embodiments, the material precursor and active species are provided into the reaction chamber at least partially simultaneously. In some embodiments, the method comprises a purge after providing the material precursor into the reaction chamber and/or after providing active species into the reaction chamber.

In some embodiments, the material comprising silicon, carbon and nitrogen forms a layer.

In some embodiments, the method is performed at a temperature of between about 150 and about 650° C. In some embodiments, the method is performed at a pressure between about 2 Torr and about 9 Torr.

In some embodiments, the wet etch resistance ratio of the material comprising silicon, carbon and nitrogen is 0.1 or less relative to thermal SiO₂. In some embodiments, the carbon content of the material comprising silicon, carbon and nitrogen is at between about 3 at-% and about 30 at-%.

In some embodiments, the substrate comprises a gap, and the material comprising silicon, carbon and nitrogen is deposited inside of the gap. In some embodiments, the gap comprises a side wall, the material comprising silicon, carbon and nitrogen forms a layer, and the conformality of the layer along the side wall is at least 90%.

In one aspect, a layer comprising silicon, carbon and nitrogen is disclosed. The layer is formed by the methods disclosed herein. claims. In some embodiments, the wet etch resistance ratio of the layer comprising silicon, nitrogen and carbon is 0.1 or less relative to thermal SiO₂. In some embodiments, the carbon content of the layer comprising silicon, nitrogen and carbon is at between about 3 at-% and about 40 at-%.

In another aspect, a semiconductor processing assembly for processing a substrate is disclosed. The semiconductor processing assembly comprises a reaction chamber constructed and arranged to hold a substrate, a reactant source constructed and arranged to contain and evaporate a material precursor comprising a silicon-containing azole an active species generated from a plasma gas source constructed and arranged to contain a gas for plasma generation, a plasma generator to generate plasma from the gas for plasma generation and a reactant injection system constructed and arranged to provide the material precursor into the reaction chamber in a vapor phase and to provide plasma into the reaction chamber.

In some embodiments, the semiconductor processing assembly according to the current disclosure further comprises a second plasma gas source constructed and arranged to contain a second gas for plasma generation. In some embodiments of the semiconductor processing assembly, the active species generated from a plasma gas source contains Ar, and the second plasma gas source contains hydrogen.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings:

FIG. 1 is a block diagram of exemplary embodiments of a method according to the current disclosure.

FIG. 2 is a schematic presentation of exemplary embodiments of a method according to the current disclosure.

FIG. 3 is an exemplary layer comprising silicon, nitrogen and carbon according to the disclosure.

FIG. 4 is a schematic drawing of an embodiment of a semiconductor processing assembly according to the current disclosure.

It will be appreciated that elements in the figures are illustrated for simplicity and clarity, and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, layers, precursors, devices and processing assemblies provided below is merely exemplary and is intended for purposes of illustration only. Although certain embodiments and examples are disclosed below, it will be understood by those in the art that the invention extends beyond the specifically disclosed embodiments and/or uses of the invention and obvious modifications and equivalents thereof. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

In an aspect, a method of depositing a material comprising silicon, carbon and nitrogen (i.e. material comprising SiCN or SiCN) on a substrate is disclosed. The method comprises providing the substrate in a reaction chamber, providing a material precursor into the reaction chamber in a vapor phase and providing active species generated from plasma into the reaction chamber to form a material comprising silicon, carbon and nitrogen on the substrate. In the disclosure, the material precursor comprises a silicon-containing azole.

Thus, a method of depositing a material comprising silicon, carbon and nitrogen (“material comprising SiCN” or “SiCN”) on a substrate, such as semiconductor substrate, is disclosed. The method may be used in, for example, manufacture of semiconductor devices, such as CFETs. Other The current methods offer the possibility to form conformal etch-stop layers in FEOL, as well as in next generation 3D NAND.

### Substrate

As used herein, the term “substrate” may refer to any underlying material or materials that may be modified, or upon which, a device, a circuit, material or a material layer may be deposited. A substrate, such as a semiconductor substrate, can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like deposited within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

A “substrate” may also be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate or a semiconductor substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

In some embodiments, a substrate is a semiconductor substrate comprising a gap. Exemplary embodiments of the disclosure can be used to fill gaps, such as trenches, vias, and/or areas between fins on a surface of a substrate. A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap. A gap may comprise a top and a bottom. A top of a gap is the area at the opening of the gap (“gap opening”), and the bottom of the gap is the part of the gap distal to the gap opening.

In some embodiments, the width of the gap may be from about 5 nm to about 6,000 nm. For example, the width of the gap may be from about 4 nm to about 4,000 nm, from about 5 nm to about 1,000 nm, from about 10 nm to about 500 nm, or about 20 nm. In some embodiments, the width of the gap may be from about 100 nm to about 800 nm, such as about 150 nm, 200 nm, 250 nm, 400 nm, 350 nm, 500 nm, 700 nm or 2,000 nm. In other embodiments, the width of the gap may be from about 3 nm to about 50 nm, such as from about 3 nm to 10 nm, from about 3 nm to 20 nm, from about 3 nm to about 30 nm, from about 3 nm to about 40 nm. As an example, the width of the gap may be about 4 nm, about 5 nm, about 6 nm, about 8 nm or about 12 nm, about 15 nm, about 18 nm, about 25 nm or about 35 nm.

In some embodiments, the depth of the gap is from about 50 nm to about 16 μm, or about 10 μm. Examples of applications in which the depth of the gap may be in the micrometer range, may include VNAND applications, or other circumstances in which a hole is etched through a stack. Such etching may take place in one or more, such a two steps. For example, the depth of the gap may be from about 50 nm to about 4 μm, from about 50 nm to about 2 μm, from about 50 nm to about 1 μm or from about 50 nm to about 500 nm. In additional examples, the depth of gap may be from about 50 nm to about 200 nm, from about 50 nm to about 200 nm, or from about 200 nm to about 7 μm, from about 200 nm to about 5 μm, from about 200 nm to about 3 μm, from about 200 nm to about 1 μm, or from about 200 nm to about 500 nm.

In some embodiments, the width to depth aspect ratio of the gap is between approximately 1:0.5 to 1:250. In certain embodiments, the width to depth aspect ratio of the gap is between approximately 1:1 to 1:200, between approximately 1:1 to 1:100, between approximately 1:0.5 to 1:50, such as 1:2, 1:3, 1:5, 1:8, 1:10, 1:15, 1:20, 1:50, or 1:150.

### Reaction Chamber

The deposition process according to the current disclosure is performed in a reaction chamber. Thus, the method of depositing material comprising SiCN according to the current disclosure comprises providing a substrate in a reaction chamber. In other words, a substrate is brought into space where the deposition conditions can be controlled.

In the method according to the current disclosure, the material precursor may be in vapor phase when it is in a reaction chamber. The material precursor may be partially gaseous or liquid, or even solid at some points in time prior to being provided in the reaction chamber. In other words, a material precursor may be solid, liquid or gaseous, for example, in a precursor vessel or other receptacle before delivery in a reaction chamber. Various means of bringing the material precursor into gas phase can be applied when delivery into the reaction chamber is performed. Such means may include, for example, heaters, vaporizers, gas flow or applying lowered pressure, or any combination thereof.

The reaction chamber of the current disclosure may be a part of a semiconductor processing assembly. The reaction chamber can form part of an ALD assembly. The reaction chamber can form part of a CVD assembly. The processing assembly may be an ALD or a CVD processing assembly. The CVD or ALD assembly is configured and arranged for plasma-enhanced deposition methods, such as PECVD and PEALD. Thus, the semiconductor processing assembly may be a PECVD assembly or a PEALD assembly. In some embodiments, the semiconductor processing assembly is configured and arranged for both thermal deposition processes and plasma-enhanced deposition processes. The reaction chamber may be part of a cluster tool in which different processes are performed to form an integrated circuit. Thus the semiconductor processing assembly may have reaction chambers of different configurations. However, to allow the plasma-enhanced deposition according to the current disclosure, the semiconductor processing assembly comprises a plasma generator. The assembly may be a single wafer reactor. Alternatively, the reactor may be a batch reactor. The assembly may comprise one or more multi-station deposition chambers. Various phases of method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The material comprising SiCN according to the current disclosure may be formed in a cross-flow reaction chamber. The material comprising SiCN according to the current disclosure may be deposited in a showerhead-type reaction chamber. Thus, in some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber is a single wafer ALD reactor. In some embodiments, the reaction chamber is a high-volume manufacturing single wafer ALD reactor. In some embodiments, the reaction chamber is a batch reactor for manufacturing multiple substrates simultaneously. In some embodiments, the reaction chamber is a CVD reactor.

### Material Comprising Silicon, Carbon and Nitrogen

In the current disclosure, a method of depositing a material comprising silicon, carbon and nitrogen (i.e. material comprising SiCN or SiCN) on a substrate is disclosed. The methods according to the current disclosure comprise providing a material precursor into the reaction chamber in a vapor phase and providing active species generated from plasma into the reaction chamber to form a material comprising SiCN on the substrate.

The SiCN material according to the current disclosure comprises silicon, carbon and nitrogen. The material may comprise one or more additional elements. For example, the material according to the current disclosure may comprise hydrogen (H). The proportion of hydrogen in the material depends on the specifics of the deposition process, selected precursors and other factors. The amount of hydrogen in a deposited material may be difficult to evaluate, as hydrogen is not detectable through some commonly used composition analysis techniques, such as x-ray photoelectron spectroscopy. Therefore, unless specifically mentioned, hydrogen content is omitted from the elemental compositions used in the current disclosure.

Depending on the precursors used, the SiCN material may comprise further elements, such as oxygen and/or sulfur. In some embodiments, SiCN material disclosed herein comprises oxygen (O). In such embodiments, the material precursor comprises oxygen. In some embodiments, SiCN material disclosed herein comprises sulfur (S). In such embodiments, the material precursor comprises sulfur. However, in some embodiments, SiCN material deposited according to the current disclosure does not substantially contain other elements than Si, C, N and H. In some embodiments, SiCN material deposited according to the current disclosure substantially does not contain other elements than Si, C, N and H. In some embodiments, SiCN material deposited according to the current disclosure does not contain other elements than Si, C, N and H.

In some embodiments, the material comprising silicon, carbon and nitrogen is silicon carbonitride. In some embodiments, the material comprising silicon, carbon and nitrogen is SiOCN. In some embodiments, the material comprising silicon, carbon and nitrogen is silicon oxycarbonitride.

As used herein, unless stated otherwise, the material comprising SiCN is not limited, restricted, or defined by the bonding or chemical state, for example, the oxidation state of any of Si, C, N, and/or any other element in the material comprising SiCN. In some embodiments, material comprising SiCN, such as a SiCN layer, comprises Si—C bonds and/or Si—N bonds. In some embodiments, SiCN comprises Si—H bonds in addition to Si—C and/or Si—N bonds.

In some embodiments, the material comprising silicon, carbon and nitrogen forms a layer. Thus, in some embodiments, a layer comprising a material comprising silicon, carbon and nitrogen (a SiCN layer) is deposited. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

In some embodiments, the SiCN layer is substantially continuous. In some embodiments, the SiCN layer is continuous. In some embodiments, the SiCN layer is substantially pinhole-free. In some embodiments, the SiCN layer is pinhole-free. In some embodiments, the SiCN layer has an approximate thickness of at least about 0.5 nm. In some embodiments, the SiCN layer has an approximate thickness of at least about 1 nm. In some embodiments, the SiCN layer has an approximate thickness of at least about 5 nm. In some embodiments, the SiCN layer has an approximate thickness of at least about 8 nm. In some embodiments, the SiCN layer has an approximate thickness of at least about 10 nm. In some embodiments, the SiCN layer has an approximate thickness of about 10 nm at maximum. In some embodiments, the SiCN layer has an approximate thickness from about 0.5 nm to about 10 nm. In some embodiments, substantially or completely continuous SiCN layer having a thickness of less than 15 nm, such as from about 1 nm to about 10 nm, for example about 5 nm or about 8 nm may be deposited on the substrate.

### Elemental Composition

Without limiting the current disclosure to any specific theory, the presence of carbon in a silicon and nitrogen-containing material may lower the k value of the material, while making it more etch resistant than a corresponding material without carbon. Controlling carbon content of low k material, such as SiCN, is important in many applications, such as in interlayer dielectrics, and when using the low k material as insulation between metal interconnects.

In some embodiments, the carbon content of the material comprising silicon, carbon and nitrogen according to the current disclosure is between about 2 at-% and about 50 at-%, about 5 at-% and about 45 at-%, wherein at-% is an abbreviation of atomic percent. In some embodiments, the carbon content of the material comprising silicon, carbon and nitrogen is between about 10 at-% and about 35 at-%. In some embodiments, the carbon content of the material comprising silicon, carbon and nitrogen is between about 3 at-% and about 40 at-%. In some embodiments, the carbon content of the material comprising silicon, carbon and nitrogen is between about 5 at-% and about 20 at-%. In some embodiments, the carbon content of the material comprising silicon, carbon and nitrogen is at least about 5 at-%. In some embodiments, the carbon content of the material comprising silicon, carbon and nitrogen is at least about 10 at-%. In some embodiments, the carbon content of the material comprising silicon, carbon and nitrogen is at least about 15 at-%. In some embodiments, the carbon content of the material comprising silicon, carbon and nitrogen is at least about 20 at-% or at least about 30 at-%.

In some embodiments, the carbon content of the material comprising silicon, carbon and nitrogen is at most about 5 at-%. In some embodiments, the carbon content of the material comprising silicon, carbon and nitrogen is at most about 10 at-%. In some embodiments, the carbon content of the material comprising silicon, carbon and nitrogen is at most about 20 at-%. In some embodiments, the carbon content of the material comprising silicon, carbon and nitrogen is at most about 30 at-%. In some embodiments, the carbon content of the material comprising silicon, carbon and nitrogen is at most 40 at-%. In some embodiments, the carbon content of the material comprising silicon, carbon and nitrogen is at most 45 at-%.

In some embodiments, SiCN comprises from about 20 at-% to about 50 at-% nitrogen. In some embodiments, SiCN comprises from about 30 at-% to about 50 at-%, from about 52 at-% to about 40 at-%, or from about 30 at-% to about 40 at-% nitrogen. In some embodiments, SiCN comprises about 10 at-% to about 50 at-% silicon. In some embodiments, SiCN comprises from about 10 at-% to about 50 at-%, from about 15 at-% to about 40 at-%, from about 20 at-% to about 35 at-% or from about 30 at-% to about 45 at-% silicon. In some embodiments, SiCN comprises from about 0.1 at-% to about 40 at-%, from about 0.5 at-% to about 30 at-%, from about 1 at-% to about 30 at-%, or from about 5 at-% to about 20 at-% hydrogen. In some embodiments, SiCN does not comprise oxygen.

In the methods, materials and layers disclosed herein, the Si to N ratio of the material comprising SiCN may be between about 0.7 and about 1.7, such as between 0.95 and 1.25 In some embodiments, the Si to N ratio of the material comprising SiCN is about 1. The exact value may depend on the material precursor used, and the amount of nitrogen in it. Especially, the structure of the azole ring in the material precursor may influence to the amount of N incorporated into the deposited material.

The etch resistance of a material may be measured in various ways. Wet etch resistance measurement may be used. The results may be expressed in absolute etch rate “wet etch resistance” (WER) or as a ratio of the wet etch resistance of the material of interest and a reference material (WERR). In the current, disclosure, the wet etch resistance of thermal silicon oxide (SiO2) is used as the reference value for WERR, unless otherwise indicated.

In some embodiments, the wet etch rate (WER) of the material comprising SiCN according to the current disclosure is from less than about 0.01 to about 0.2 nm/min, or from less than about 0.01 to about 0.1 nm/min, or from less than about 0.01 to about 0.05 nm/min, as measured by exposure to 0.5% HF. In some embodiments, the wet etch rate of the material comprising silicon is less than about 0.03 nm/min, or less than about 0.05 nm/min, or less than about 0.1 nm/min or less than about 0.2 nm/min as measured by exposure to 0.5% HF. In some embodiments, the WERR (wet etch rate ratio) of the material comprising SiCN is from about 0.001 to 0.01 relative to thermal SiO2. In some embodiments, the WERR of the material comprising SiCN is 0.004 or less relative to thermal SiO₂.

In some embodiments, the wet etch resistance ratio (WERR) of the material comprising SiCN is 0.5 or less relative to thermal SiO₂. In some embodiments, the WERR of the material comprising SiCN is 0.3 or less relative to thermal SiO₂. In some embodiments, the WERR of the material comprising SiCN is 0.1 or less relative to thermal SiO₂. In some embodiments, the WERR of the material comprising SiCN is 0.07 or less relative to thermal SiO₂. In some embodiments, the WERR of the material comprising SiCN is 0.05 or less relative to thermal SiO₂.

In one aspect, a material comprising silicon layer produced by the methods described herein is disclosed. In some embodiments, the material comprising silicon layer according to the current disclosure is substantially polyamic acid-free. In many applications, such as selective deposition, selective etching and patterning, substantially or completely pin-hole free layers may be used. It may be possible to deposit thin, such as less than 3 nm thick layers of material comprising silicon by the methods disclosed herein that are substantially or completely pinhole-free. In some embodiments, a substantially polyamic acid free material comprising silicon layer having a thickness of less than about 15 nm, or less than about 10 nm or less than about 5 nm or less than about 3 nm is disclosed.

### Material Precursor

In the current disclosure, the material precursor comprises a silicon-containing azole. Thus, the material precursor used contains all the main constituent elements—Si, C and N—of the deposited layer. However, the incorporation of the three elements into the deposited material is not straightforward. Especially in embodiments, in which the process is a CVD process, but also in ALD processes, albeit through possibly different mechanisms, the breakdown of the material precursor may influence the proportions of Si, C and N into the deposited materials. Without limiting the current disclosure to any specific theory, some material may form volatile byproducts that leave the reaction chamber without being incorporated into the deposited material. The formed volatile products may depend on the specific structure of the material precursor molecule that influences the likelihood of a bond breaking due to, for example, differences in bond strength.

The azole is a five-membered aromatic heterocycle containing at least one nitrogen atom. In some embodiments, the azole of the material precursor consists of carbon, nitrogen and hydrogen. In some embodiments, the azole contains one nitrogen atom. In some embodiments, the azole contains two nitrogen atoms. In some embodiments, the azole contains one nitrogen atom and one oxygen atom. In some embodiments, the azole contains one nitrogen atom and one sulfur atom. An azole containing two nitrogen atoms may be an imidazole (nitrogen atoms in ring positions 1 and 3) or a pyrazole (nitrogen atoms in ring positions 1 and 2). Examples of triazoles are 1,2,3-triazole and 1,2,4-triazole. In some embodiments, the azole of the material precursor is selected from a group consisting of imidazole, pyrazole, triazole, tetrazole, pentazole. In some embodiments, the azole of the material precursor is imidazole. In some embodiments, the azole of the material precursor is pyrazole. In some embodiments, the azole of the material precursor is triazole. In some embodiments, the azole of the material precursor is tetrazole. In some embodiments, the azole of the material precursor is pentazole.

In some embodiments, the azole of the material precursor consists of carbon, nitrogen, oxygen and hydrogen. In some embodiments, the azole of the material precursor is selected from a group consisting of oxazole, isoxazole and oxadiazole. Examples of oxadiazoles are 1,2,4-oxadiazole, furazan (1,2,5-oxadiazole) and 1,3,4-oxadiazole.

In some embodiments, the azole of the material precursor consists of carbon, nitrogen, sulfur and hydrogen. In some embodiments, the material comprising silicon, carbon and nitrogen further comprises sulfur. In some embodiments, the material precursor is selected from a group consisting of thiazole, isothiazole and thiadiazole. Examples of thiadiazoles are 1,2,3-thiadiazole, 1,2,4-thiadiazole, 1,2,5-thiadiazole and 1,3,4-thiadiazole.

In some embodiments, the azole ring is bonded to a silyl group. The silyl group may be bonded to the azole ring through nitrogen in position 1 of the azole group and a silicon atom of the silyl group. The silyl group may contain one silicon atom. The silyl group may contain two silicon atoms (a disilyl group).

In some embodiments, the azole ring is bonded to an alkylsilyl group. Thus, in some embodiments, the material precursor comprises an alkylsilyl group bonded to the azole ring. In some embodiments, the alkylsilyl group is bonded to the azole through a nitrogen atom. For example, the alkylsilyl group may be bonded to the azole ring through nitrogen in position 1 of the azole group and a silicon atom of the alkylsilyl group. The alkylsilyl group may contain one silicon atom. The alkylsilyl group may contain two silicon atoms (a disilyl group). An alkylsilyl group comprises a silicon atom bonded to at least one alkyl group. In some embodiments, the alkyl group contains a silicon atom boned to one alkyl group. In some embodiments, the alkyl group contains a silicon atom boned to two alkyl groups. In some embodiments, the alkyl group contains a silicon atom boned to three alkyl groups. Each of the alkyl groups bonded to a silicon atom may be independently selected from C1 to C4 alkyls. In some embodiments, each R is a C1 to C2 alkyl. Each alkyl group may independently be linear, branched or cyclic. Each alkyl group may independently be saturated or unsaturated.

In some embodiments, each alkyl group in the alkylsilyl group is the same alkyl. In some embodiments, an alkyl group comprises one silicon atom bonded to three identical alkyl groups. In some embodiments, an alkyl group comprises one silicon atom bonded to two identical alkyl groups and one hydrogen atom or a different alkyl group.

For example, the alkylsilyl group can have the formula —SiR₃, wherein each R is an H or a C1 to C4 alkyl, with the proviso that at least one R is an alkyl. In some embodiments, all three R are C1 to C4 alkyl groups. In some embodiments, all R are the same alkyl. In some embodiments, the alkylsilyl groups comprises at least two different alkyl groups. In some embodiments, all R are methyl or ethyl. In some embodiments, the alkylsilyl group is —Si(CH₃)₃ (i.e. all R are methyl). In some embodiments, the alkylsilyl group is —Si(CH₂CH₃)₃ (i.e. all R are ethyl). In some embodiments, the alkylsilyl group is —Si(CH₂CH₃)₂CH₃. In some embodiments, the alkylsilyl group is —Si(CH₂CH₃)(CH₃)₂. In some embodiments, the alkylsilyl is —Si(CH₂CH₂CH₃)₃. In some embodiments, the alkylsilyl is —Si(CH₂CH₂CH₃)(CH₃)₂. In some embodiments, the alkylsilyl is —Si(CH₂CH₂CH₃)₂(CH₃).

The alkylsilyl group may comprise additional functional groups, such as —OH, —NH₂, —SH₂.

As the current disclosure relates to vapor deposition processes, the material precursor is provided into the reaction chamber in a vapor phase. Thus, the material precursor needs to be sufficiently volatile and/or to have a sufficient vapor pressure to be delivered into the reaction chamber. However, the vapor pressure may be regulated through temperature, and volatilization of the material precursor may be enhanced by employing low pressure. Further, what is considered to be sufficient volatility and/or vapor pressure, depends on the application in question. Generally, however, smaller molecules are more volatile, but the elemental composition and the molecular structure of the compound may significantly influence the volatility of a given molecule.

In some embodiments, a silicon-containing group in a silicon-containing azole according to the current disclosure is attached to the azole ring through a nitrogen atom. Examples of such molecules include (trimethylsilyl)imidazole, such as 1-(trimethylsilyl)imidazole, 1-[(1,1-dimethylethyl)dimethylsilyl]-1H-imidazole, 1-(isopropyldimethylsilyl)imidazole, 1-(ethyldimethylsilyl)-1H-imidazole, 2-methyl-1-(trimethylsilyl)-1H-imidazole, 4-methyl-1-(trimethylsilyl)-1H-imidazole, 1-(triethylsilyl)-1H-imidazole, 2-ethyl-4-methyl-1-(trimethylsilyl)-1H-imidazole, 4-ethenyl-1-(trimethylsilyl)-1H-imidazole, 2-ethyl-1-(trimethylsilyl)-1H-imidazole.

In some embodiments, a silicon-containing group in a silicon-containing azole according to the current disclosure is attached to the azole ring through a carbon atom. Examples of such molecules include 1-methyl-5-(trimethylsilyl)-1H-imidazole, 5-(trimethylsilyl)-1H-imidazole, 4-(trimethylsilyl)-2H-1,2,3-triazole, 1-methyl-2-(trimethylsilyl)-1H-imidazole, 1-ethyl-2-(trimethylsilyl)-1H-imidazole, 2-[(1,1-dimethylethyl)dimethylsilyl]-1-methyl-1H-imidazole. In some embodiments, the azole ring of the silicon-containing azole comprises oxygen. Examples of such molecules are 5-(trimethylsilyl)oxazole and 2-ethyl-5-(trimethylsilyl)oxazole. In some embodiments, the azole ring of the silicon-containing azole comprises sulfur. Examples of such molecules are 5-(trimethylsilyl)thiazole and 4-methyl-5-(trimethylsilyl)thiazole

In some embodiments, the material precursor is selected from a group consisting of 1-trimethylsilylimidazole and 1-trimethylsilyl-1,2,4-triazole.

In addition to a silyl group, the azole ring may comprise additional side chains in various positions. For example, one or more, such as two or three, methyl or ethyl groups may be bonded to the azole ring. Although in many embodiments, a silyl group is attached to the nitrogen at position 1 of the azole ring, a silyl group may be attached to any other position of the azole ring. Consequently, it is possible that the nitrogen at position 1 of the azole ring may have another group, such as an alkyl group, attached to it. In some embodiments, the material precursor is a compound in which the azole group is an imidazole group, a trialkylsilane is bonded to the nitrogen atom at position 1 of the azole ring, and the azole ring does not contain additional side chains. In some embodiments, the material precursor is a compound in which the azole group is an imidazole group, a trialkylsilane is bonded to the nitrogen atom at position 1 of the azole ring, and the azole ring contain an additional C1 or C2 side chain in position 2 or position 3 of the azole ring.

Thus, the method according to the current disclosure may comprise heating the material precursor prior to providing it to the reaction chamber. In some embodiments, the material precursor is heated to at least 60° C., to at least 70° ° C., or to at least 100° C., or to at least 120° C. or to at least 150° C. or to at least 180 ºC or to at least 200° ° C. in the vessel. In some embodiments, the material precursor is heated to at most 350° C. or to at most 250° C. or to at most 200° C. or to at most 150° C., or to at most 100° ° C., or to at most 80° C., or to at most 70° C. Also the injection system may be heated to improve the vapor phase delivery of the material precursor to the reaction chamber.

In some aspects, a five-membered aromatic ring structure, to which a silicon-containing group is attached (as detailed above) may comprise only one nitrogen atom and no additional heteroatoms. Such molecules are termed pyrrolides. The current disclosure can be extended to such chemistries. In other words, a material precursor comprising a silicon group-containing pyrrolide may find advantages in the methods according to the current disclosure. The silicon-containing groups and alkyl groups can be as described for azoles.

### Deposition of Material Comprising Silicon, Carbon and Nitrogen

By deposition in the current disclosure is meant depositing or forming material on the substrate using plasma-enhanced CVD (PECVD), cyclic PECVD or plasma-enhanced ALD (PEALD). The methods according to the current disclosure comprise providing a material precursor into the reaction chamber in a vapor phase and providing active species generated from plasma into the reaction chamber to form a material comprising silicon, carbon and nitrogen on the substrate. A material precursor is provided into the reaction chamber in a vapor phase. Thus, the current disclosure relates to vapor-deposition of materials. The methods disclosed herein may be vapor deposition processes. In this disclosure, “gas” can include material that is a gas at normal temperature and pressure (NTP), a vaporized solid and/or a vaporized liquid, and can be constituted by a single gas or a mixture of gases, depending on the context. The material precursor may be provided to the reaction chamber in gas phase. The term “inert gas” can refer to a gas that does not take part in a chemical reaction and/or does not become a part of a layer to an appreciable extent. Exemplary inert gases include He, Ne and Ar, as well as any combination thereof. In some cases, molecular nitrogen and/or hydrogen can be an inert gas. A gas other than a process gas, i.e., a gas introduced without passing through a reactant injection system, other gas distribution device, or the like, can be used for, e.g., sealing the reaction space, and can include a seal gas.

In addition to providing a material precursor into the reaction chamber, active species generated from plasma are provided into the reaction chamber. Due to providing both a material precursor and active species into the reaction chamber, material comprising silicon, nitrogen and carbon is formed on the substrate. In other words, the substrate provided in the reaction chamber is contacted with a material precursor and with active species generated from a plasma.

In the methods according to the current disclosure, plasma is provided into the reaction chamber to form an active species for forming material comprising SiCN on the substrate. Thus, the deposition methods according to the current disclosure may be termed plasma-enhanced deposition methods. Examples of plasma-enhanced deposition methods include plasma-enhanced atomic layer deposition (PEALD), plasma-enhanced chemical vapor deposition (PECVD) and cyclic plasma-enhanced CVD (cyclic PECVD). The process may comprise one or more cyclic phases. In some embodiments, the process comprises or one or more continuous (i.e. acyclic) phases. In some embodiments, the deposition process comprises the continuous flow of at least one of a material precursor and active species generated from a plasma. In such embodiments, the process comprises a continuous flow of a material precursor or active species generated from a plasma. In some embodiments, the process comprises a continuous flow of a material precursor and active species generated from a plasma.

In some embodiments, the material precursor and the active species are provided into the reaction chamber cyclically. The method may thus comprise at least one deposition cycle comprising providing material precursor and active species generated from a plasma into the reaction chamber. In some embodiments, the material precursor and active species are provided into the reaction chamber alternately and sequentially. In some embodiments, the material precursor and active species are provided into the reaction chamber at least partially simultaneously. In some embodiments, the method comprises a purge after providing the material precursor into the reaction chamber and/or after providing active species into the reaction chamber.

In some embodiments, the deposition of a material comprising SiCN comprises a cyclic deposition process. The cyclic deposition process according to the current disclosure may be PEALD or cyclic PECVD. The term “cyclic deposition process” can refer to the sequential introduction of precursor(s) (such as a material precursor) and/or reactant(s) (such as active species generated from a plasma) into a reaction chamber to deposit material, such as a material comprising SiCN, on a substrate. A duration of providing a material precursor or active species generated from a plasma into the reaction chamber may be called precursor pulse time and plasma pulse time, respectively. The process may comprise a purge step between providing a material precursor into the reaction chamber and providing active species generated from plasma into the reaction chamber, or after providing active species generated from plasma into the reaction chamber, or both.

Generally, in cyclic deposition processes according to the current disclosure, such as atomic layer deposition (ALD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. In the current disclosure, the second reactant comprises active species generated from a plasma. The second precursor or a reactant can be capable of further reaction with the precursor. Without limiting the current disclosure to any specific theory, the active species generated from a plasma may induce reactions between or within the material precursor molecules leading to the accumulation of the material comprising SiCN on the substrate surface. Alternatively or in additions, the active species generated from plasma may react selectively with specific bonds in the material precursor, such as Si—H bonds. This may beneficially affect the etch resistance of the deposited SiCN.

Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a material precursor into the reaction chamber. In some embodiments, the cyclic deposition process comprises purging the reaction chamber after providing an active species generated from a plasma into the reaction chamber. In some embodiments, the cyclic deposition process comprises purging the reaction chamber after providing a material precursor into the reaction chamber, and after providing active species generated from a plasma into the reaction chamber. Without limiting the current disclosure to any specific theory, PEALD processes may display slower and more controllable layer growth speed compared to PECVD.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. In the current disclosure, plasma is used to decompose the material precursor. The substrate and/or reaction space can be heated to promote the reaction between the gaseous precursor and/or reactants, such as material precursor and active species generated from a plasma. In some embodiments the precursor(s) and reactant(s) are provided until a layer having a desired thickness is deposited. In some embodiments, cyclic CVD processes can be used with multiple cycles to deposit a layer having a desired thickness. In cyclic CVD processes, the precursors and/or reactants, such as active species generated from a plasma may be provided to the reaction chamber in pulses that do not overlap, or that partially or completely overlap.

In some embodiments, plasma may be formed remotely via plasma discharge (“remote plasma”) away from the substrate or reaction chamber. In some embodiments, plasma may be formed in the vicinity of the substrate or directly above substrate (“direct plasma”). In some embodiments, the plasma is produced by gas-phase ionization of a gas with a radio frequency (RF) power. The power for generating RF-generated plasma can be varied in different embodiments of the current disclosure. In some embodiments, the RF power is between 20 W and 1,500 W. In some embodiments, the RF power may be from 20 W to 1000 W, such as from 20 W to 800 W. In some embodiments, the RF power is between 50 W and 1,500 W. In some embodiments, the RF power may be from 100 W to 1,500 W, such as from 200 W to 1,500 W or from about 500 W to 1,500 W. For example, the RF power may be 100 W, 200 W, 500 W, 700 W, 1,000 W or 1,200 W. Adjusting the power of the RF plasma generator during the deposition of the material comprising SiCN may affect the amount/density and energy of active species generated by plasma. Without limiting the current invention to any specific theory, higher RF power may lead to generation of higher energy ions and radicals. This may affect the damage the active species cause on the surfaces of the substrate, but, conversely, may increase the efficiency of deposition.

In plasma-enhanced deposition, the chemical reactions are promoted by active species in plasma and/or generated by plasma. Therefore, lower temperatures compared to thermal (i.e. processes excluding plasma) may be used. Thus, using plasma-enhanced deposition processes, such as PEALD, cyclic PECVD or PECVD, the thermal budget of the manufacturing process may be decreased. In some embodiments, the vapor deposition process according to the current disclosure is a plasma-enhanced CVD process. In some embodiments, the vapor deposition process according to the current disclosure is a cyclic plasma-enhanced CVD process. In some embodiments, the vapor deposition process according to the current disclosure is a plasma-enhanced ALD process. In some embodiments, the material comprising silicon, nitrogen and carbon is deposited by PECVD. In some embodiments, the material comprising silicon, nitrogen and carbon is deposited by cyclic PECVD. In some embodiments, the material comprising silicon, nitrogen and carbon is deposited by PEALD.

In some embodiments, the material precursor and the reactive species generated from a plasma are provided into the reaction chamber during one deposition cycle. Thus, a deposition process comprises at least one deposition cycle in which a material precursor and reactive species generated from a plasma are provided into the reaction chamber. In some embodiments, substantially all the deposition cycles of a deposition process comprise providing the material precursor and the reactive species generated from a plasma into the reaction chamber. The deposition cycle may be repeated a predetermined number of times to achieve desired thickness of material comprising SiCN. For example, a deposition cycle may be repeated from 1 to about 2,000, or from about 5 to about 1,000, or from about 10 to about 1,000, or from about 100 to about 1,000 times. In some embodiments, a deposition cycle is repeated from about 3 to about 500, or from about 5 to about 500, or from about 10 to about 500, or from about 50 to about 500. The number of repetitions of the deposition cycle depends on the per-cycle growth rate (GPC) of the material comprising SiCN and of the desired thickness of the material.

The material precursor may be provided to the reaction chamber holding the substrate in a single pulse or in a sequence of multiple pulses. In some embodiments, the material precursor is provided in a single long pulse. In some embodiments, the material precursor is provided in multiple shorter pulses. The reactive species generated from a plasma may be provided into the reaction chamber holding the substrate in a single pulse or in a sequence of multiple pulses. In some embodiments, the reactive species generated from a plasma is provided in a single long pulse. In some embodiments, the reactive species generated from a plasma are provided into the reaction chamber multiple shorter pulses. For example, a deposition cycle may comprise providing a material precursor into the reaction chamber in a single pulse, then providing the reactive species generated from a plasma into the reaction chamber in multiple pulses. The pulses may be provided sequentially.

The process may or may not comprise purge between pulses. However, in some embodiments, providing the material precursor and the reactive species generated from a plasma into the reaction chamber may at least partially overlap or at least one of the precursors may be provided into the reaction chamber continuously. In some embodiments, the material precursor and the reactive species generated from a plasma are co-pulsed, i.e. the two precursors are provided at least partially simultaneously into the reaction chamber. In some embodiments, the pulses of the material precursor and the reactive species generated from a plasma overlap partially. In some embodiments, the pulses of the material precursor and the reactive species generated from a plasma overlap completely. A deposition process may be any combination of above deposition schemes.

Material comprising SiCN, such as a SiCN layer, may be deposited by providing a material precursor and reactive species generated from a plasma into the reaction chamber. In some embodiments, the process is a cyclic deposition method. Thus, in some embodiments, providing the material precursor and the reactive species generated from a plasma into the reaction chamber is repeated. A SiCN layer of desired thickness may be deposited by a cyclic deposition process. In some embodiments, providing the material precursor and the reactive species generated from a plasma is repeated at least five times. In some embodiments, providing the material precursor and the reactive species generated from a plasma is repeated at least 50 times. In some embodiments, providing the material precursor and the reactive species generated from a plasma is repeated at least 100 times. In some embodiments, providing the material precursor and the reactive species generated from a plasma is repeated at least 200 times. In some embodiments, providing the material precursor and the reactive species generated from a plasma is repeated at least 400 times. In some embodiments, providing the material precursor and the reactive species generated from a plasma is repeated at least 600 times. In some embodiments, the material precursor and the reactive species generated from a plasma are provided alternately and sequentially into a reaction chamber to deposit a material comprising SiCN. In some embodiments, the method according to the current disclosure is a cyclic deposition method and comprises providing the material precursor and the reactive species generated from a plasma into the reaction chamber alternately and sequentially. The reaction chamber may be purged after providing the material precursor into the reaction chamber and/or providing reactive species generated from a plasma into the reaction chamber.

In some embodiments the substrate is held at a temperature of greater than about 150° C. during at least one deposition cycle, i.e. the method is performed at a temperature of greater than about 150° C. In some embodiments the substrate is held at a temperature of greater than about 200° C. during at least one deposition cycle. In some embodiments the substrate is held at a temperature of greater than about 250° C. during at least one deposition cycle. In some embodiments the substrate is held at a temperature of greater than about 400° C., or greater than about 500 ºC, or greater than about 600° C. during at least one deposition cycle. In some embodiments the substrate is held at a temperature of greater than about 350° C. during at least one deposition cycle. In some embodiments the substrate is held at a temperature of greater than about 200° C. during at least one deposition cycle. In some embodiments the substrate is held at a temperature of less than about 650° C., or less than about 550° C. during at least one deposition cycle. In some embodiments the substrate is held at a temperature of less than about 350° C. during at least one deposition cycle. In some embodiments the substrate is held at a temperature of less than about 400° C. during at least one deposition cycle. In some embodiments the substrate is held at a temperature of less than about 250° C. during at least one deposition cycle. In some embodiments the method is performed at a temperature of less than about 200° C. during at least one deposition cycle. In some embodiments, the method is performed at a temperature of between about 150 and about 650° C. In some embodiments, the temperature in the reaction chamber is substantially the same throughout the deposition process.

In some embodiments, material comprising SiCN may be deposited at a temperature from about 150° ° C. to about 650° C. For example, material comprising silicon may be deposited at a temperature from about 200° ° C. to about 650° C., or at a temperature from about 250° C. to about 650° C., or at a temperature from about 400° C. to about 650° C., or at a temperature from about 500° C. to about 650, or at a temperature from about 550° ° C. to about 650. In some embodiments, the substrate is heated before providing the material precursor into the reaction chamber. In some embodiments, the deposition process according to the current disclosure may be performed at ambient temperature. In some embodiments, ambient temperature is room temperature (RT). In some embodiments, ambient temperature may vary between 20° C. and 30° C.

The growth rate of the material comprising silicon, carbon and nitrogen depends on the deposition process used, and on the process parameters used. Typically, in continuous PECVD growth may be the fastest, for example at least from about 1 nm/min to about 10 nm/minute, such as about 2 nm/min or about 3 nm/min or about 5 nm/min. In cyclic deposition processes, growth rate is typically measured as growth per cycle (GPC). In pulsed PECVD (i.e. cyclic PECVD), the growth rate may be, for example, from about 0.1 Å/cycle to about 5 Å/cycle, such as from about 0.5 Å/cycle to about 5 Å/cycle or from about 1 Å/cycle to about 5 Å/cycle or from about 2 Å/cycle to about 5 Å/cycle. In some embodiments, the growth rate of the material comprising silicon, carbon and nitrogen is from about 2 Å/cycle to about 4 Å/cycle, such as about 3.3 Å/cycle or about 3.5 Å/cycle. In some embodiments, material comprising silicon, nitrogen and carbon is deposited by PEALD. In such embodiments, the growth rate is typically lower than in any of the PECVD methods, as ideally, the material growth per cycle is self-limiting. In some embodiments, material comprising silicon, nitrogen and carbon is deposited by PEALD and the growth rate of the material comprising silicon, nitrogen and carbon is from about 0.01 Å/cycle to about 1 Å/cycle, such as from about 0.01 Å/cycle to about 0.5 Å/cycle or from about 0.01 Å/cycle to about 0.2 Å/cycle or from about 0.01 Å/cycle to about 0.1 Å/cycle, such as about 0.05 Å/cycle. In some embodiments, utilizing PEAL, the growth rate of the material comprising silicon, nitrogen and carbon is from about 0.1 Å/cycle to about 1 Å/cycle, such as from about 0.5 Å/cycle to about 1 Å/cycle or from about 0.2 Å/cycle to about 1 Å/cycle or from about 0.7 Å/cycle to about 1 Å/cycle.

In some embodiments, the substrate comprises a gap, and the material comprising silicon, carbon and nitrogen is deposited inside of the gap. In some embodiments, the gap comprises a side wall, the material comprising silicon, carbon and nitrogen forms a layer, and the conformality of the layer along the side wall is at least 90%. In some embodiments, the gap comprises a side wall, the material comprising silicon, carbon and nitrogen forms a layer, and the conformality of the layer along the side wall is at least 95%. In the current disclosure, unless otherwise stated, conformality means [the thickness of the material in the vicinity of the bottom of the side wall of the gap]/[thickness of the material in the vicinity of the top of the side wall of the gap]. 100%. By the vicinity of the top and bottom of the sidewall is meant the first 20% of the depth of the gap from the top or bottom, respectively. The conformality is typically evaluated by TEM, or in some cases, SEM.

In one aspect, a layer comprising silicon, carbon and nitrogen is disclosed (SiCN layer). The layer is formed by the methods disclosed herein. Thus, the material properties of the SiCN layer correspond to that of the material comprising SiCN disclosed herein. For example, in some embodiments, the wet etch resistance ratio of the layer comprising silicon, nitrogen and carbon is 0.1 or less relative to thermal SiO₂, and in some embodiments, the carbon content of the layer comprising silicon, nitrogen and carbon is at between about 2 at-% and about 50 at-%, such as between about 3 at-% and about 40 at-%.

In some embodiments, the active species are generated from a gas comprising a noble gas. In some embodiments, the noble gas is selected from a group consisting of helium, neon argon and krypton. In some embodiments, the noble gas is helium. In some embodiments, the noble gas is argon. In some embodiments, the gas comprising a noble gas contains two noble gases. In some embodiments, the gas comprising a noble gas contains helium and argon. In some embodiments, the active species are generated from a gas comprising argon and hydrogen. In some embodiments, the active species are generated from a gas comprising helium, argon and hydrogen. In some embodiments, the hydrogen content of the gas from which the active species are generated is below about 5%, such as below about 3% or below about 1%. In some embodiments, the hydrogen content of the gas from which the active species are generated is below about 0.5%, such as below about 0.3% or below about 0.1% or below about 0.1%. For example, the hydrogen content of the

### Purging

As used herein, the term “purge” may refer to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of chemistries which react with each other. However, purging may be effected between two pulses of chemistries that do not react with each other. For example, a purge, or purging may be provided between providing a precursor into the reaction chamber and providing active species generated from a plasma. Purging may avoid, or at least reduce, gas-phase interactions between the two substances reacting with each other in gas phase. It shall be understood that a purge can be effected either in time or in space, or both. For example in the case of temporal purges, a purge step can be used e.g. in the temporal sequence of providing a material precursor (such as a material precursor) into a reactor chamber, providing a purge gas to the reactor chamber, and providing a second precursor or a reactant (such as active species generated from a plasma) into the reactor chamber, wherein the substrate on which a material is deposited does not move. For example in the case of spatial purges, a purge step can take the following form: moving a substrate from a first location to which a material precursor is continually supplied, through a purge gas curtain or another type of a hindrance to gas movement between locations, to a second location to which a second precursor or a reactant is continually supplied. Purging times may be, for example, from about 0.01 seconds to about 20 seconds, or from about 0.05 s to about 10 s, or from about 0.1 s to about 10 s, or from about 0.5 s to about 10 s, or between about 0.1 s and about 5 seconds, or between about 0.5 s and about 1 seconds, such as 0.2 s, 0.3 s, 0.5 s or 1 s. However, other purge times can be utilized if necessary, such as where highly conformal step coverage over high aspect ratio structures or other structures with complex surface morphology is needed, or in specific reactor types, such as a batch reactor, may be used.

### Pressure

The methods according to the current disclosure may be performed in reduced pressure relative to the ambient pressure. In some embodiments, a pressure within the reaction chamber during the deposition process according to the current disclosure is less than about 500 Torr, or a pressure within the reaction chamber during the deposition process is between about 0.01 Torr and about 500 Torr, or between about 0.01 Torr and about 100 Torr, or between about 0.01 Torr and about 10 Torr. In other words, the method may be performed at a pressure of less than about 500 Torr. In some embodiments, a pressure within the reaction chamber during the deposition process is less than about 50 Torr, less than about 20 Torr, less than about 10 Torr or less than about 5 Torr. In some embodiments, the pressure of the reaction chamber is between about 2 Torr and about 9 Torr during the deposition process. For example, the pressure during the deposition process may be about 1 Torr, about 3 Torr or about 5 Torr. A pressure in a reaction chamber may be selected independently for different process steps. In some embodiments, a substantially constant or a constant pressures is used during a deposition process.

### Other Aspects

Further, the current disclosure relates to a semiconductor processing assembly for processing a substrate. Thus, a semiconductor processing assembly for processing a substrate is disclosed. The semiconductor processing assembly comprises a reaction chamber constructed and arranged to hold a substrate, a reactant source constructed and arranged to contain and evaporate a material precursor comprising a silicon-containing azole an active species generated from a plasma gas source constructed and arranged to contain a gas for plasma generation, a plasma generator to generate plasma from the gas for plasma generation and a reactant injection system constructed and arranged to provide the material precursor into the reaction chamber in a vapor phase and to provide plasma into the reaction chamber.

In some embodiments, the semiconductor processing assembly according to the current disclosure further comprises a second plasma gas source constructed and arranged to contain a second gas for plasma generation. In some embodiments of the semiconductor processing assembly, the active species generated from a plasma gas source contains Ar, and the second plasma gas source contains hydrogen.

The methods disclosed herein may be useful in the manufacture of semiconductor devices. For example, a layer comprising silicon, carbon and nitrogen (a SiCN layer) may be deposited. Correspondingly, in a yet another aspect, a method of fabricating a semiconductor device is disclosed. The method comprises depositing a layer comprising silicon, carbon and nitrogen on a surface of a semiconductor substrate according to the current disclosure.

### Drawings

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

The particular implementations shown and described are illustrative of the invention are not intended to otherwise limit the scope of the aspects and implementations in any way. Indeed, for the sake of brevity, conventional manufacturing, connection, preparation, and other functional aspects of the methods and assemblies according to the current disclosure may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

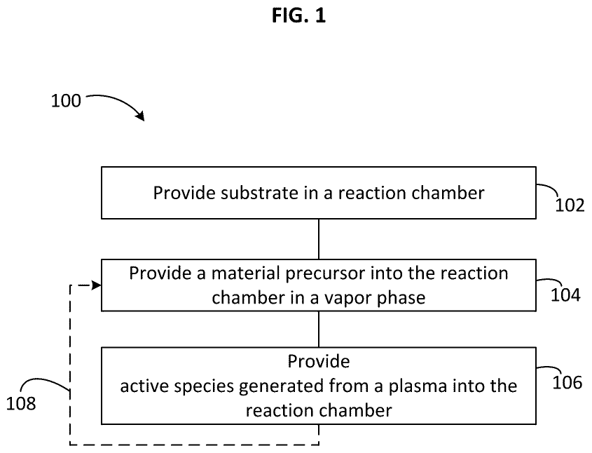

FIG. 1 is a block diagram of exemplary embodiments of a method according to the current disclosure.

FIG. 1 is a block diagram of a method 100 to deposit material comprising silicon, nitrogen and carbon in accordance with exemplary embodiments of the current disclosure. In the first phase 102, a substrate, optionally comprising a gap, is provided in a reaction chamber. A substrate according to the current disclosure may comprise, for example, an oxide, such as silicon oxide, for example thermal silicon oxide or native silicon oxide) or other materials disclosed herein. The deposited material comprising silicon, nitrogen and carbon may be used in the manufacture of electronic devices.

The reaction chamber can form part of a CVD or ALD assembly. The reaction chamber may be a single wafer reactor. Alternatively, the reactor may be a batch reactor. The assembly may comprise one or more multi-station deposition chambers. In some embodiments, the method 100 is performed in a single reaction chamber of a cluster tool, but other, preceding or subsequent, manufacturing steps of the structure or device are performed in additional reaction chambers of the same cluster tool.

A material precursor is provided into the reaction chamber containing the substrate at phase 104. Without limiting the current disclosure to any specific theory, the material precursor may at least partially chemisorb on the substrate during providing the material precursor into the reaction chamber. Providing the material precursor into the reaction chamber may be continuous or performed in pulses. The duration of a material precursor pulse (material precursor pulse time) may be, for example, from about 0.1 to about 15 seconds, from about 0.5 to about 10 seconds, from about 0.5 to about 5 seconds, or from about 0.1 seconds to about 1.5 seconds, or from about 0.1 seconds to about 1 second, or from about 0.1 seconds to about 0.8 seconds, or from about 0.1 seconds to about 0.5 seconds. In some embodiments, the material precursor pulse length is below 1 second, such as 0.2 seconds, 0.3 seconds or 0.7 seconds.

When active species generated from a plasma are provided into the reaction chamber at phase 106, they may react with the material precursor, or its derivate species, in the gas phase or on the substrate to form the material comprising silicon, nitrogen and carbon. Providing the active species generated from a plasma into the reaction chamber may be continuous or performed in pulses. The duration of a plasma pulse (plasma pulse time) may be, for example from about 0.1 to about 15 seconds, from about 0.5 to about 10 seconds, from about 0.5 to about 5 seconds, or from about 0.5 to about 3 seconds. In some embodiments, the active species generated from a plasma pulse time may be shorter than 25 s, shorter than 15 s, shorter than 8 s, shorter than 5 s, or shorter than 2 s.

If the material precursor and the active species generated from a plasma are provided into the reaction chamber continuously, providing them is continued until a desired amount of material is deposited. The desired amount depends on the application in question. For example, the deposition may be continued from about 0.5 seconds to several hours, such as from about 0.5 seconds to about 60 minutes, or from about 0.5 seconds to about 30 minutes, or from about 0.5 seconds to about 10 minutes, or from about 0.5 seconds to about 1 minute. In some embodiments, the deposition is continued from about 5 seconds to about 2 hours, or from about 5 seconds to about 30 minutes, or from about 10 seconds to about 60 minutes, or from about 10 seconds to about 15 minutes, or from about 20 seconds to about 60 minutes.

In some embodiments, the material precursor is heated before providing it into the reaction chamber. In some embodiments, the material precursor is kept in ambient temperature before providing it to the reaction chamber.

Phases 104 and 106, performed in any order if pulsing regime is used for at least one of the material precursor and the active species generated from a plasma, may form a deposition cycle. In some embodiments, the two phases deposition, namely providing the material precursor into the reaction chamber and providing active species generated from a plasma into the reaction chamber (104 and 106), may optionally be repeated (dashed loop 108). In such embodiments, the methods contain several deposition cycles. The thickness of the material comprising silicon, nitrogen and carbon may be regulated by adjusting the number of deposition cycles. The deposition cycle (loop 108) may be repeated until a desired material (such as layer) thickness is achieved. For example, about 50, 100, 200, 400, 400, 500, 700, 800 or 1,000, deposition cycles may be performed. The growth speed of the material deposited according to the methods disclosed herein may be relatively fast. However, the final thickness of the deposited material may be affected by optional treatments, which may lead to shrinking of the deposited material.

Although phases 104 and 106 are depicted as separate phases, in many embodiments, the process phases may overlap. Specifically, providing a material precursor into the reaction chamber and providing plasma into the reaction chamber may overlap partially or completely. One of the phases 104 and 106 may also be performed continuously, while the other one may be performed in a pulsed manner. Loop 108 may be absent in embodiments which are not cyclic.

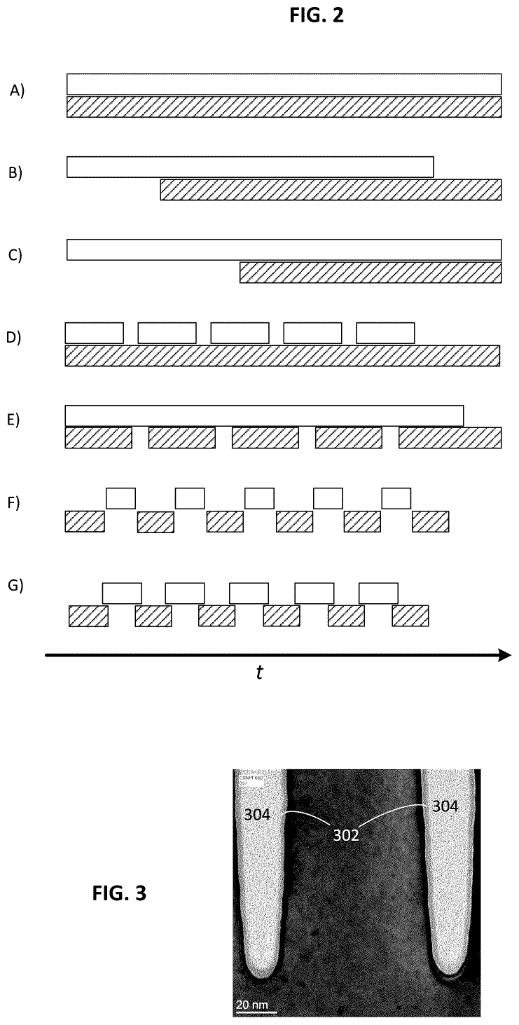

FIG. 2 is a schematic presentation of embodiments according to the current disclosure. FIG. 2 illustrates the possibility of overlapping phases. Timeline is indicated at the bottom of FIG. 2 by an arrow, providing material precursor into the reaction chamber is indicated with a white bar, and providing active species generated from a plasma is depicted with hatching. The lengths of the bars depicting process phases, as well as embodiments depicted in different panels are not drawn to scale.

In panel A, a simple process involving constant flow of the material precursor and providing active species generated from a plasma continuously is indicated. In the illustration, both are initiated and stopped at the same time, but either of the two could be initiated earlier, and, independently, one could be stopped earlier, as indicated in panels B) and C). In the embodiment of panel B) the material precursor is provided into the reaction chamber before the active species generated from a plasma are provided into the reaction chamber, and the active species generated from a plasma are provided into the reaction chamber longer than material precursor is provided therein. In the embodiment of panel C), the material precursor is provided into the reaction chamber significantly earlier than the active species generated from a plasma are provided therein, and both are stopped at the same time.

In panel D) the material precursor is pulsed, and the active species generated from a plasma are provided into the reaction chamber continuously. In panel E), the pulsing scheme is the opposite, and the material precursor is provided into the reaction chamber continuously, and the active species generated from a plasma are provided into the reaction chamber in pulses. In both panels D) and E), the active species generated from a plasma are provided after providing of the material precursor has been stopped.

In panels F) and G), the material precursor and the active species generated from a plasma are provided into the reaction chamber alternatively. In panel F), they are provided into the reaction chamber alternately and sequentially, i.e. that the pulses do not overlap. Although not depicted in panel F), there may be a purge between providing the material precursor into the reaction chamber and providing active species generated from a plasma into the reaction chamber. In panel G) providing material precursor into the reaction chamber and providing active species generated from a plasma into the reaction chamber partially overlap. The degree of overlap may vary according to the specifics of the process.

It should be noted that all purge phases have been omitted from the schematic presentations. However, in some embodiments, purge may be used to regulate the process, and/or to remove side products from the reaction chamber.

FIG. 3 is a transmission electron micrograph of an exemplary layer 302 comprising silicon, nitrogen and carbon according to the disclosure. The layer comprising silicon, nitrogen and carbon 302 has been deposited in a gap 304 on the substrate surface. As visible in the picture, a uniform layer 302 has been deposited along the side wall of the gap. The top of the gap is not visible in the figure, but the top of the figure is within top 20% of the gap depth. Some accumulation of the material comprising silicon is visible at the bottom of the gap 304. Better uniformity between bottom and side wall of the gap 304 may be achieved through isotropic trimming of the deposited layer, for example by using plasma etch.

The deposition was performed with argon and H₂. RF power for plasma generation was from 100 W to 700 W, the plasma pulse duration from 0.3 seconds to 4 seconds, and pressure in the reaction chamber was 5 Torr. Helium was used as a seal gas.

In some additional experiments, plasma power between 200 W and 500 W was used, with pressure in the deposition chamber between 5 and 8 Torr. Plasma pulse duration was less than 3 seconds, with H₂ to a Ar ratio in the atmosphere below 0.3.

In some further experiments, plasma power of below 600 W was used, with pressure in the deposition chamber below 7 Torr. Plasma pulse duration was 3 seconds, with H₂ to a Ar ratio in the atmosphere again below 0.25.

In some embodiments, the ratio of thickness of the deposited material on a sidewall relative to the bottom was from about 0.6 to about 1.4, such as about 0.7 or about 0.93 or about 0.91 or about 1.

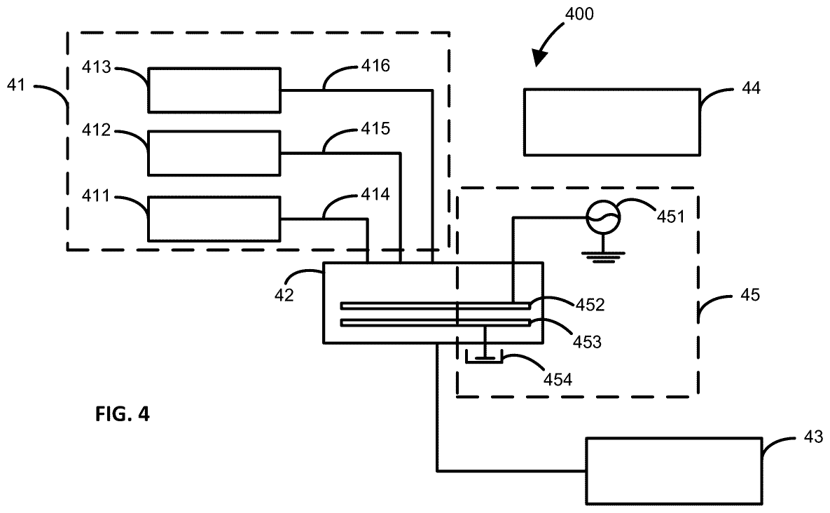

FIG. 4 illustrates a semiconductor processing assembly 400 according to the current disclosure in a schematic manner. The processing assembly 400 comprises one or more reaction chambers 42 constructed and arranged to hold the substrate, a reactant injection system 41 constructed and arranged to provide a material precursor into the reaction chamber 400 in a vapor phase, and a plasma generation system 45 to provide active species generated from plasma into the reaction chamber 42.

The processing assembly 400 comprises a first reactant source 411 constructed and arranged to contain and evaporate the material precursor comprising a silicon-containing azole, a first plasma gas source 412 constructed and arranged to contain a first gas for plasma generation, and a second plasma gas source 413 constructed and arranged to contain a second gas for plasma generation. The semiconductor processing assembly 400 is constructed and arranged to provide the material precursor via the reactant injection system 41 to the reaction chamber 42, and to generate plasma by the plasma generation system 45 to provide it into the reaction chamber 42 for depositing material comprising silicon, nitrogen and carbon on the substrate.

Processing assembly 400 can be used to perform a method as described herein. In the illustrated example, processing assembly 400 includes one or more reaction chambers 42, a reactant injection system 41, a first reactant source 411, a first plasma gas source 412, a second plasma gas source 413, an exhaust source 43 and a controller 44. The processing assembly 400 may comprise one or more additional gas sources (not shown), such as an inert gas source, a carrier gas source and/or a purge gas source. Reaction chamber 42 can include any suitable reaction chamber, such as an PEALD or PECVD reaction chamber as described herein.

The first reactant source 411 can include a vessel and a material precursor comprising a silicon-containing azole as described herein—alone or mixed with one or more carrier (e.g., inert) gases. A first plasma gas source 412 can include a vessel and a gas for generating a first plasma, such as noble gas as described herein. A second plasma gas source 413 can include a gas for generating a second plasma, such as hydrogen plasma as described herein. Thus, although illustrated with three sources 411-413, processing assembly 400 can include any suitable number of reactant sources. Reactant sources 411-413 can be coupled to reaction chamber 42 via lines 414-416, which can each include flow controllers, valves, heaters, and the like. In some embodiments, each of the reactant sources 411-413 may be independently heated or kept at ambient temperature. In some embodiments, a reactant vessel is heated so that a precursor or a reactant reaches a suitable temperature for vaporization and/or delivery into the reaction chamber 42.

Exhaust source 43 can include one or more vacuum pumps.

The semiconductor processing assembly 400 comprises a plasma generation system 45 for generating the plasma used in the processes according to the current disclosure. The plasma generation system 45 may be provided with a RF power source 451 operably connected with the controller, and constructed and arranged to produce a plasma from the selected gas, such as argon, hydrogen, or a combination thereof.

The plasma-enhanced cyclic deposition process according to the current disclosure may be performed using the semiconductor processing assembly 400. For example, a pair of electrically conductive flat-plate electrodes 452, 453 in parallel and facing each other in the interior (reaction zone) of the reaction chamber 42 may be provided, RF power (e.g., 13.56 MHz or 27 MHz) from a power source 451 may be provided to one side, and the other side may be electrically grounded 454, leading to excitation of a plasma between the electrodes 452, 453.

A substrate may be placed on the lower electrode 453, the lower electrode 453 thus serving as a susceptor. The lower electrode 453 may also comprise a temperature regulator, keeping a temperature of the substrate placed thereon relatively constant. The upper electrode 452 can serve as a shower plate, and precursor gases and optionally an inert gas(es) and/or purging gases can be introduced into the reaction chamber 42 through gas lines 414-416, respectively, and through the shower plate 452.

During operation of a processing assembly 400, substrates, such as semiconductor wafers (not illustrated), are transferred into the reaction chamber 42. Once substrate(s) are transferred to reaction chamber 42, one or more gases from gas sources, such as precursors, carrier gases, and/or purge gases, are introduced into reaction chamber 42. Plasma is generated at suitable points in time to provide active species into the reaction chamber for depositing material comprising silicon, nitrogen and carbon on the surface of the substrate.

Controller 44 includes electronic circuitry and software to selectively operate valves, manifolds, heaters, pumps and other components included in the processing assembly 400. Such circuitry and components operate to introduce precursors, reactants and purge gases from the respective sources. Controller 44 can control timing of gas and plasma pulse sequences, temperature of the substrate and/or reaction chamber 42, pressure within the reaction chamber 42, plasma generation, and various other operations to provide proper operation of the processing assembly 400. Controller 44 can include control software to electrically or pneumatically control valves to control flow of precursors, reactants and purge gases into and out of the reaction chamber 42. Controller 44 can include modules such as a software or hardware component, which performs certain tasks. A module may be configured to reside on the addressable storage medium of the control system and be configured to execute one or more processes.

Other configurations of processing assembly 400 are possible, including different numbers and kinds of precursor and reactant sources. For example, a reaction chamber 42 may comprise more than one, such as two or four, deposition stations. Such a multi-station configuration may have advantages in, for example, complex deposition processes. Further, it will be appreciated that there are many arrangements of valves, conduits, precursor sources, and reactant sources that may be used to accomplish the goal of selectively and in coordinated manner feeding gases into reaction chamber 42. Further, as a schematic representation of a processing assembly, many components have been omitted for simplicity of illustration, and such components may include, for example, various valves, manifolds, purifiers, heaters, containers, vents, and/or bypasses.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various methods and assemblies, and other features, functions, acts, and/or properties disclosed herein, as well as any and all equivalents thereof.

1. A method of depositing a material comprising silicon, carbon and nitrogen on a substrate, the method comprising:
providing the substrate in a reaction chamber;
providing a material precursor into the reaction chamber in a vapor phase; and
providing active species generated from plasma into the reaction chamber to form a material comprising silicon, carbon and nitrogen on the substrate;
wherein the material precursor comprises a silicon-containing azole.

2. The method of claim 1, wherein the active species are generated from a gas comprising a noble gas.

3. The method of claim 2, wherein the active species are generated from a gas comprising argon and hydrogen.

4. The method of claim 1, wherein the material precursor comprises an alkylsilyl group bonded to the azole ring.

5. The method of claim 4, wherein the alkylsilyl group has the formula —SiR₃, and each R is a H or a C1 to C4 alkyl, with the proviso that at least one R is an alkyl.

6. The method of claim 5, wherein all three R groups are C1 to C4 alkyl groups.

7. The method of claim 6, wherein all R are methyl or ethyl

8. The method of claim 4, wherein the alkylsilyl group is bonded to the azole through a nitrogen atom.

9. The method of claim 1 wherein the azole of the material precursor consists of carbon, nitrogen and hydrogen.

10. The method of claim 9, wherein the azole of the material precursor is selected from the group consisting of imidazole, pyrazole, triazole, tetrazole, and pentazole.

11. The method of claim 1, wherein the azole of the material precursor consists of carbon, nitrogen, oxygen, and hydrogen.

12. The method of claim 1, wherein the azole of the material precursor consists of carbon, nitrogen, sulfur, and hydrogen.

13. The method of claim 1, wherein the material precursor is selected from the group consisting of 1-trimethylsilylimidazole and 1-trimethylsilyl-1,2,4-triazole.

14. The method of claim 1, wherein the material precursor and the active species are provided into the reaction chamber cyclically.

15. The method of claim 14, wherein the material precursor and active species are provided into the reaction chamber alternately and sequentially.

16. The method of claim 1, wherein the wet etch resistance ratio of the material comprising silicon, carbon and nitrogen is 0.1 or less relative to thermal SiO₂.

17. The method of claim 1, wherein the carbon content of the material comprising silicon, carbon and nitrogen is at between about 3 at-% and about 40 at-%.

18. The method of claim 1, wherein the Si to N ratio of the material comprising silicon, carbon and nitrogen is between about 0.95 and about 1.25.

19. The method of claim 1, wherein the substrate comprises a gap, and the material comprising silicon, carbon and nitrogen is deposited inside of the gap.

20. The method of claim 19, wherein the gap comprises a side wall, the material comprising silicon, carbon and nitrogen forms a layer, and the conformality of the layer along the side wall is at least 90%.
